(19) United States
(12) Patent Application Publication
(10) Pub. No.: US 2008/0073717 A1
(43) Pub. Date: Mar. 27, 2008

(54) Semiconductor devices having substrate plug and methods of forming the same

(76) Inventors: Tae-Hong Ha, Suwon-si (KR); Jong-Mil Youn, Yongin-si (KR); Hoon Lim, Seoul (KR); Hoo-Sung Cho, Yongin-si (KR); Jae-Hun Jeong, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/785,676

(22) Filed: Apr. 19, 2007

(30) Foreign Application Priority Data
Sep. 26, 2006 (KR) 10-2006-0093595

(51) Int. Cl. H01L 27/06; H01L 21/02

(52) U.S. Cl. 257/347; 438/151; 257/E21.002; 257/E27.011

(57) ABSTRACT

A semiconductor device includes a device isolation layer disposed in a substrate and defining an active region, a first gate pattern on the active region, a first insulating layer on the substrate and the first gate pattern, a first body region on the first insulating layer, and a first substrate plug extending from the substrate into the first insulating layer, the first substrate plug penetrating the device isolation layer and contacting the substrate under the device isolation layer.

### BACKGROUND OF THE INVENTION

1. Field of the Invention

The present invention relates to semiconductor devices and methods of forming the same. More particularly, the present invention relates to semiconductor devices having a substrate plug and methods of forming the same.

2. Description of the Related Art

To increase integration density, a semiconductor device may be fabricated having body regions that are sequentially stacked on an active region. The active region may be defined by a device isolation layer disposed in a semiconductor substrate, which may be, e.g., single-crystalline silicon. The body regions may be sequentially stacked on the active region by performing a selective epitaxial process on the active region, using the active region as a seed. Accordingly, the body regions may be formed using the single-crystalline silicon of the active region. Gate patterns may be respectively formed on the body regions and the active region.

However, as a design rule of the semiconductor device is reduced, it may be difficult to form single-crystalline body regions, e.g., single-crystalline silicon body regions, using the selective epitaxial process. In particular, the area of the active region may be reduced by the reduced design rule of the semiconductor device. The body regions may be formed by performing the selective epitaxial process using the active region and the device isolation layer as a seed. As a result, the body regions may have amorphous silicon due to the device isolation layer, which may consequently deteriorate electrical characteristics of the semiconductor device due to the amorphous silicon.

It may be desirable to stack a plurality of body regions on a respective plurality of stacked active regions, e.g., in a structure wherein first, second, third, etc., active layers are sequentially stacked on a substrate such as a single-crystalline silicon substrate, a silicon-on-insulator (SOI) substrate, etc. Such a structure could be formed by, e.g., epitaxial growth of the stacked layers using corresponding underlying layers as seed layers by employing a plug structure to propagate the single-crystalline structure. However, reducing the design rule in such a structure could reduce a distance between the plug structure and a gate pattern, such that a spacer on a sidewall of the gate structure, e.g., a nitride spacer, comes into contact with the plug structure, preventing epitaxial growth of the single-crystalline layer from propagating through the plug structure to the overlying layer(s). Accordingly, there is a need for a semiconductor device having a body region on an active layer, and a method of forming the same.

### SUMMARY OF THE INVENTION

The present invention is therefore directed to semiconductor devices having a substrate plug and methods of forming the same, which substantially overcome one or more of the problems due to the limitations and disadvantages of the related art.

It is therefore a feature of an embodiment of the present invention to provide a semiconductor device having a substrate plug extended from a substrate to form a body region on an active region, the substrate plug passing through a device isolation layer.

It is therefore another feature of an embodiment of the present invention to provide a method of forming a semiconductor device having a substrate plug and at least one body region on a single-crystalline active region.

At least one of the above and other features and advantages of the present invention may be realized by providing a semiconductor device including a device isolation layer disposed in a substrate and defining an active region, a first gate pattern on the active region, a first insulating layer on the substrate and the first gate pattern, a first body region on the first insulating layer, and a first substrate plug extending from the substrate into the first insulating layer, the first substrate plug penetrating the device isolation layer and contacting the substrate under the device isolation layer.

The device may further include a second insulating layer on the first body region and the first insulating layer, a second body region on the second insulating layer, and a second substrate plug extending from the first substrate plug into the second insulating layer. The active region, the first and second body regions, and the first and second substrate plugs may include a single-crystalline material. The single-crystalline material may be single-crystalline silicon.

The first body region may be disposed on a first side of the first substrate plug, and the device may further include another body region on the first insulating layer, wherein the other body region may be on a same plane as the first body region, and the other body region may be disposed on a second side of the first substrate plug opposite the first side.

The device may further include a first diffusion region in the active region between the first gate pattern and the first substrate plug, a second gate pattern on the first body region, a second diffusion region in the first body region; the second diffusion region being between the second gate pattern and the first substrate plug, and a first node plug extending through the first insulating layer and electrically connecting the first diffusion region to the second diffusion region.

The first node plug and the first substrate plug may extend in parallel from the substrate, and the first node plug may extend beyond the first substrate plug. The device may further include a second insulating layer on the second gate pattern and the first body region, wherein the second insulating layer may include a lower portion that extends toward the substrate beyond the second diffusion region, and a second substrate plug may be disposed in the lower portion, the second substrate plug contacting the first substrate plug.

The device may further include a spacer on a sidewall of the first gate pattern, wherein the spacer may be between the first gate pattern and the first node plug, and the first node plug may be between the spacer and the first substrate plug. The device may be a volatile memory device. The device may be a nonvolatile memory device.

At least one of the above and other features and advantages of the present invention may be realized by providing a method of forming a semiconductor device including forming a device isolation layer in a substrate, the device isolation layer defining an active region, forming a first gate pattern on the active region, forming a first insulating layer on the substrate and the first gate pattern, forming a first body region on the first insulating layer, and forming a first substrate plug that extends from the substrate into the first insulating layer, the first substrate plug penetrating the device isolation layer and contacting the substrate under the device isolation layer.

Forming the first body region and the first substrate plug may include forming a first body growth layer that extends from the substrate through the device isolation layer to at least partially cover the first insulating layer, and removing a portion of the first body growth layer that directly overlies the device isolation layer. Forming the first body region and the first substrate plug may further include forming a photoresist pattern on the first body growth layer, the photoresist pattern exposing the portion of the first body growth layer, and etching the first body growth layer to expose a portion of the first insulating layer, wherein the photoresist pattern serves as an etching mask and the first insulating layer serves as an etching buffer layer. The first body growth layer may include a single-crystalline material.

The method may further include forming a second insulating layer on the first body region and the first insulating layer, wherein the second insulating layer may be disposed in an opening formed by the removal of the portion of the first body growth layer, and forming a second substrate plug in the second insulating layer, the second substrate plug contacting the first substrate plug.

Forming the first body growth layer may include forming a photoresist layer on the first insulating layer, the photoresist layer exposing a portion of the first insulating layer that directly overlies the device isolation layer, forming a contact hole by etching the exposed portion of the first insulating layer and the device isolation layer using the photoresist layer as an etching mask, the contact hole exposing a portion of the substrate under the device isolation layer, removing the photoresist layer, forming a single-crystalline first substrate plug layer in the contact hole using the exposed portion of the substrate as a seed, and forming a single-crystalline first body layer on the first insulating layer and the first substrate plug layer using the first substrate plug layer as a seed. Forming the single-crystalline first substrate plug layer may include an epitaxial process, and forming the single-crystalline first body layer may include annealing the first body layer to convert it from an amorphous material to a single-crystalline material.

The method may further include forming a second insulating layer on the first body region and on the first substrate plug, forming a second body region on the second insulating layer, and forming a second substrate plug that extends from the first substrate plug into the second insulating layer. The method may further include forming a first diffusion region in the active region between the first gate pattern and the first substrate plug, forming a second gate pattern on the first body region, forming a second diffusion region in the first body region; the second diffusion region being between the second gate pattern and the first substrate plug, and forming a first node plug that extends through the first insulating layer and electrically connects the first diffusion region to the second diffusion region.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a layout view of a semiconductor device in accordance with an embodiment of the present invention;

FIG. 2 illustrates a cross-sectional view taken along line I-I′ of FIG. 1; and

FIGS. 3 through 8 illustrate cross-sectional views of stages in a method of forming a semiconductor device.

### DETAILED DESCRIPTION OF THE INVENTION

Korean Patent Application No. 2006-93595, filed on Sep. 26, 2006, in the Korean Intellectual Property Office, and entitled: “Semiconductor Devices Having Substrate Plug and Methods of Forming the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

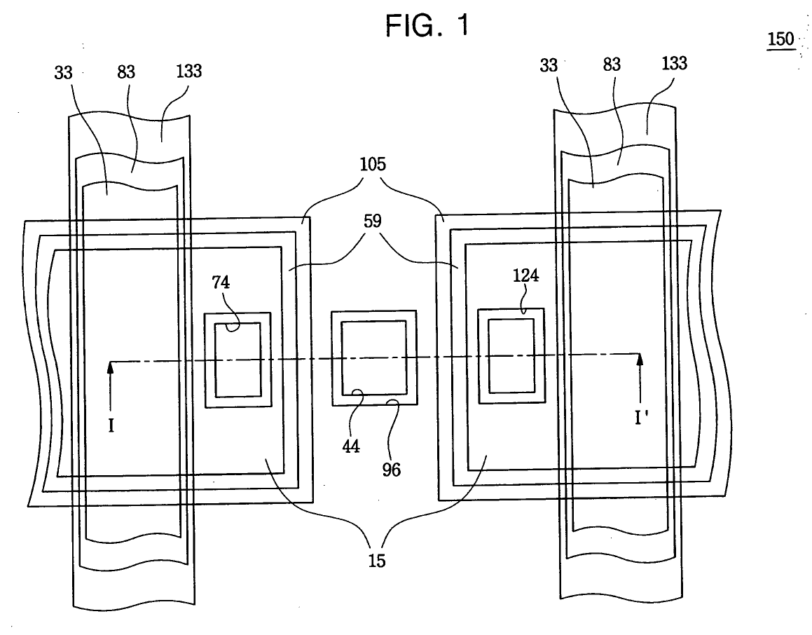

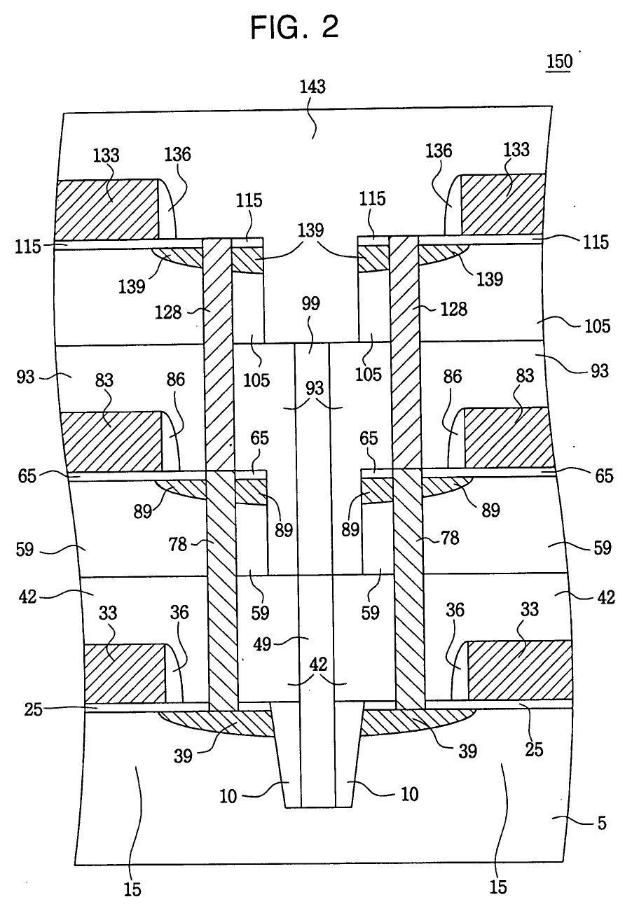

FIG. 1 illustrates a layout view of a semiconductor device in accordance with an embodiment of the present invention, and FIG. 2 illustrates a cross-sectional view taken along line I-I′ of FIG. 1.

The semiconductor device may include a substrate having an active region defined by a device isolation layer in the substrate, and a plurality of stacked body regions that may be formed by sequentially propagating a single-crystalline structure of a substrate to the respective body regions using a plug structure. The plug structure may include a plug that passes through the device isolation layer to contact the substrate. Accordingly, the plug structure may be disposed apart from features formed in the stacked body regions.

In detail, a semiconductor device 150 may include a device isolation layer 10 disposed in a substrate 5, as shown in FIG. 2. The substrate 5 may be, e.g., a semiconductor substrate. The device isolation layer 10 may define active regions 15. The device isolation layer 10 may include, e.g., silicon oxide, a material having metal or non-metal atoms in a lattice of silicon oxide, etc. The substrate 5 may have a single-crystalline layer, e.g., a single-crystalline silicon layer. The substrate 5 may have an N- or P-type conductivity. The semiconductor device 150 may be, e.g., a volatile or nonvolatile memory device.

Lower body regions 59 may be respectively disposed on the active regions 15. Upper body regions 105 may be respectively disposed on the lower body regions 59. Although not shown, additional body regions may be sequentially formed on the active regions 15. The lower and upper body regions 59 and 105 may include, e.g., an undoped single-crystalline material such as single-crystalline silicon.

First, second and third gate patterns 33, 83 and 133 may be respectively disposed on the active regions 15, and the lower and upper body regions 59 and 105. The first, second and third gate patterns 33, 83 and 133 may include, e.g., doped polysilicon or metal nitride in a volatile device. Each of the first, second and third gate patterns 33, 83 and 133 may include, e.g., doped polysilicon and metal silicide stacked thereon in a volatile device, two conductive materials and silicon oxide, silicon nitride and silicon oxide which are sequentially stacked between the two conductive materials in a non-volatile device, etc.

A buried insulating layer 42 may be disposed on the active regions 15, between the active region 15 and the lower body region 59. A protective insulating layer 93 may be disposed on the lower body regions 59, between the lower body regions 59 and the upper body regions 105. The protective insulating layer 93 may be disposed on the buried insulating layer 42 to cover the second gate pattern 83 and the lower body region 59. The buried insulating layer 42 may be disposed to cover the first gate pattern 33, the active region 15 and the device isolation layer 10. The buried insulating layer 42 and the protective insulating layer 93 may include, e.g., silicon oxide, a material having metal or nonmetal atoms in a lattice of silicon oxide, etc.

A substrate plug may extend from the substrate 5 through the device isolation layer 10 into at least one of the overlying insulating and/or protective layers. In an implementation, a lower substrate plug 49 may be sequentially disposed in the device isolation layer 10 and the buried insulating layer 42, and an upper substrate plug 99 may be disposed on the lower substrate plug 49 in the protective insulating layer 93. The lower substrate plug 49 may contact the substrate 5, passing through the device isolation layer 10. The portion of the substrate 5 contacted by the lower substrate plug 49 may be single-crystalline.

The upper substrate plug 99 may contact the lower substrate plug 49, passing through the protective insulating layer 93. The lower and upper substrate plugs 49 and 99 may be a same material as the lower and upper body regions 59 and 105, e.g., a single-crystalline material such as single-crystalline silicon.

A node plug may extend from an active region 15 and may be connected to an overlying body region. In an implementation, first node plugs 78 may be disposed to electrically connect the active regions 15 to the respective lower body regions 59, and second node plugs 128 may be disposed to electrically connect the lower body regions 59 to the respective upper body regions 105. Each first node plug 78 may be disposed to contact the active region 15, passing through the lower body region 59 and the buried insulating layer 42. Each second node plug 128 may be disposed to contact the lower body region 59, and may pass through the upper body region 105 and the protective insulating layer 93. The first and second node plugs 78 and 128 may include metal nitride and metal stacked thereon, doped polysilicon, etc.

Diffusion regions 39, 89 and 139 may be respectively disposed in the active region 15, and the lower and upper body regions 59 and 105. The first, second and third gate patterns 33, 83 and 133 may overlap the respective diffusion regions 39, 89 and 139. The first and second node plugs 78 and 128 may be disposed to electrically contact each other, and may pass through the diffusion regions 89 of the lower body regions 59. First, second and third gate spacers 36, 86 and 136 may be respectively disposed on sidewalls of the first, second and third gate patterns 33, 83 and 133. The first, second and third gate spacers 36, 86 and 136 may include, e.g., silicon nitride.

First, second and third gate insulating layers 25, 65 and 115 may be respectively disposed between the first gate patterns 33 and the active regions 15, between the second gate patterns 83 and the lower body regions 59, and between the third gate patterns 133 and the upper body regions 105. The first, second and third gate insulating layers 25, 65 and 115 may include, e.g., silicon oxide, a material having metal or nonmetal atoms in a lattice of silicon oxide, etc. A planarization insulating layer 143 may be disposed on the protective insulating layer 93 and may cover the upper body regions 105 and the third gate patterns 133. The planarization insulating layer 143 may include a same material as the protective insulating layer 93, or may be a different material from the protective insulating layer 93.

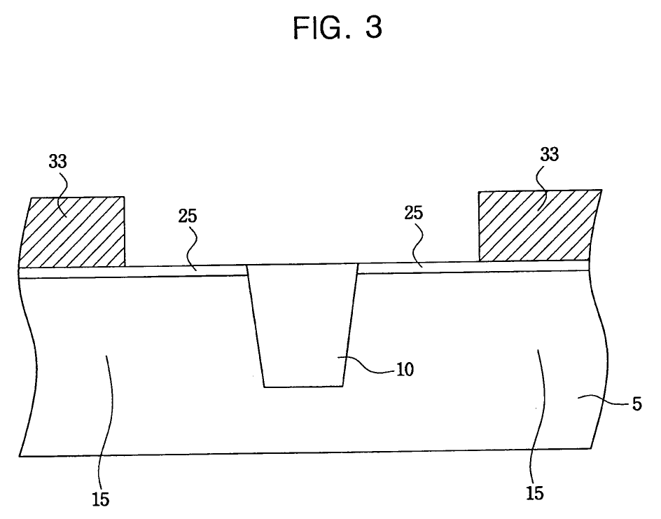

A method of forming a semiconductor device having a substrate plug in accordance with an embodiment of the present invention will now be described with reference to FIGS. 3 through 8, which illustrate cross-sectional views of stages in a method of forming a semiconductor device.

Referring to FIG. 3, a device isolation layer 10 may be formed on a substrate 5. The device isolation layer 10 may define active regions 15. The device isolation layer 10 may be formed using, e.g., silicon oxide, a material of metal or nonmetal atoms in a lattice of silicon oxide, etc. The substrate 5 may be doped, e.g., to have an N-type conductivity, a P-type conductivity, etc. The substrate 5 may include a single-crystalline material layer such as single-crystalline silicon.

A first gate insulating layer 25 may be formed on the active regions 15. The first gate insulating layer 25 may be formed using, e.g., silicon oxide, a material of metal or nonmetal atoms in a lattice of silicon oxide, etc. Subsequently, first gate patterns 33 may be formed on the first gate insulating layer 25. The first gate patterns 33 may be formed to traverse the top surface of the active regions 15, as shown in FIG. 1.

In a volatile device, the first gate pattern 33 may be formed using, e.g., doped polysilicon or metal nitride, doped polysilicon and metal silicide stacked thereon, etc. In a nonvolatile device, the first gate pattern 33 may be formed using, e.g., two conductive materials with silicon oxide, silicon nitride and silicon oxide sequentially formed between the two conductive materials.

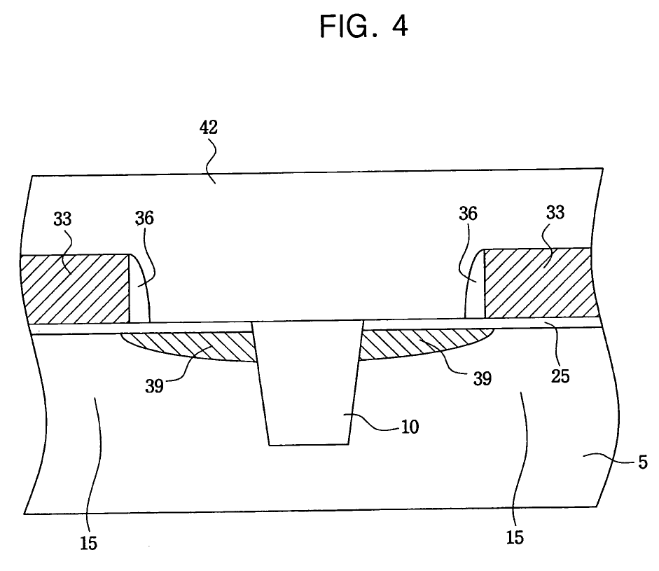

Referring to FIG. 4, first gate spacers 36 may be respectively formed on sidewalls of the first gate patterns 33. The first gate spacers 36 may be formed using, e.g., silicon nitride. Subsequently, first diffusion regions 39 may be formed in the active region 15, using the first gate patterns 33 and the first gate spacers 36 as a mask. The first gate patterns may overlap the respective first diffusion regions 39. The first diffusion regions 39 may be formed with different conductivity from the substrate 5.

A buried insulating layer 42 may be formed on the first gate insulating layer 25 and may cover the first gate patterns 33 and the first gate spacers 36. The buried insulating layer 42 may be formed of a material having a same etching rate as the device isolation layer 10, e.g., silicon oxide, a material having metal or nonmetal atoms in a lattice of silicon oxide, etc.

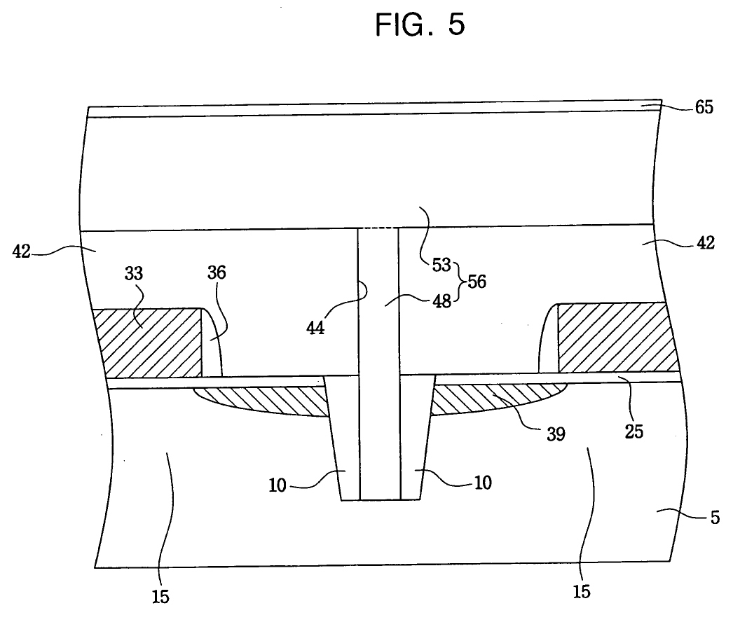

A photoresist layer (not shown) may be formed on the buried insulating layer 42 and may have an opening exposing a portion of the buried insulating layer 42. The photoresist layer may be formed using a general semiconductor photolithography process, details of which are well-known to those of skill in the art. The buried insulating layer 42 and the device isolation layer 10 may be sequentially etched using the photoresist layer as a mask to form a lower contact hole 44, as shown in FIG. 5.

The lower contact hole 44 may expose a portion of the substrate 5. The exposed portion of the substrate 5 may be single-crystalline. After the formation of the lower contact hole 44, the photoresist layer may be removed from the substrate 5. A lower substrate plug layer 48 may fill the lower contact hole 44. The lower substrate plug layer 48 may be formed by, e.g., performing a selective epitaxial process on the substrate 5 using the buried insulating layer 42 and the device isolation layer 10 as a mask. The lower substrate plug layer 48 may be formed of a single-crystalline material such as single-crystalline silicon. A top surface of the lower substrate plug layer 48 may be formed at the substantially same level as that of the buried insulating layer 42. The lower substrate plug layer 48 may be formed to be single-crystalline by using the substrate 5 as a seed and performing the selective epitaxial process.

Subsequently, a lower body layer 53 may be formed on the buried insulating layer 42. The lower body layer 53 may cover the lower substrate plug layer 48. The lower body layer 53 may be formed using, e.g., amorphous silicon. The lower body layer 53 and the lower substrate plug layer 48 may serve as a lower body growth layer 56.

In another implementation, after the formation of the lower contact hole 44, the lower body layer 53 alone may be formed on the buried insulating layer 42 and filling the lower contact hole 44. A general semiconductor annealing process may be performed on the lower body growth layer 56. During the annealing process, heat may be applied to the substrate 5 having the lower body growth layer 56 in a nitrogen ambient for a predetermined time.

Where the lower substrate plug layer 48 is formed under the lower body layer 53, the semiconductor annealing process may change the lower body layer 53 from amorphous silicon to single-crystalline silicon using the lower substrate plug layer 48 as a seed. Where the lower body layer 53 directly contacts the substrate 5, without the lower substrate plug layer 48, the annealing process may change the lower body layer 53 from amorphous silicon to single-crystalline silicon using the substrate 5 as a seed.

After the performance of the semiconductor annealing process, a second gate insulating layer 65 may be formed on the lower body layer 53. The second gate insulating layer 65 may be formed using, e.g., the same material as the first gate insulating layer 25.

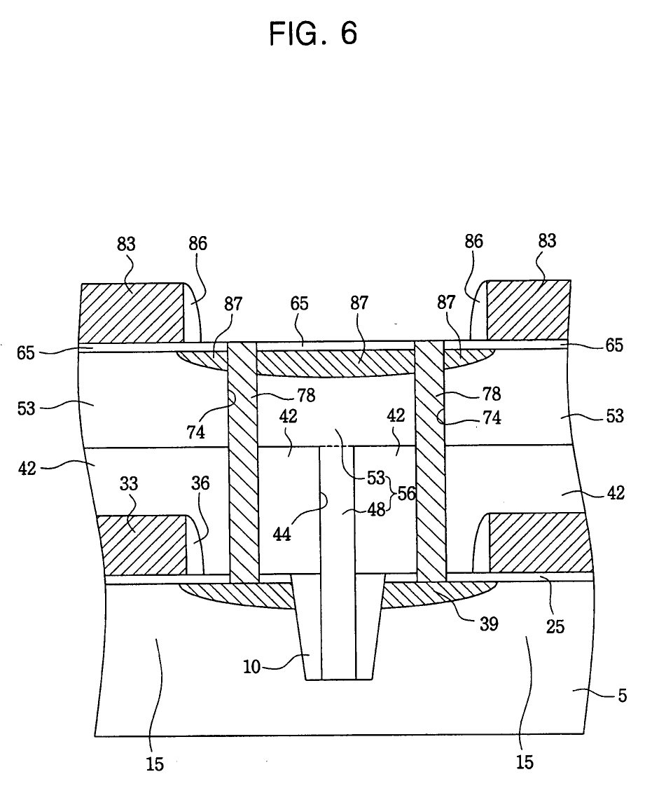

Another photoresist layer (not shown) may be formed on the second gate insulating layer 65, and may have openings exposing portions of the second gate insulating layer 65. The photoresist layer may be formed using a general semiconductor photolithography process. The second gate insulating layer 65, the lower body growth layer 56 and the buried insulating layer 42 may be sequentially etched using the photoresist layer as an etching mask to form first contact holes 74, as shown in FIG. 6. The first contact holes 74 may expose portions of the active regions 15, and may pass through the second gate insulating layer 65, the lower body layer 53, the buried insulating layer 42 and the first gate insulating layer 25. After the formation of the first contact holes 74, the photoresist layer may be removed from the substrate 5.

First node plugs 78 may be formed to respectively fill the first contact holes 74. The first node plugs 78 may contact the respective active regions 15. The first node plugs 78 may be formed using, e.g., metal nitride and metal stacked thereon, doped polysilicon, etc. Subsequently, second gate patterns 83 may be formed on the second gate insulating layer 65. The second gate patterns 83 may be spaced apart from the first node plugs 78. The second gate patterns 83 may be formed to have the same structure as the first gate patterns 33 in a volatile or nonvolatile device.

Second gate spacers 86 may be respectively formed on sidewalls of the second gate patterns 83. The second gate spacers 86 may be formed using the same material as the first gate spacers 36. A lower impurity diffusion region 87 may be formed in the lower body growth layer 56 using the second gate patterns 83 and the second gate spacers 86 as a mask. The second gate patterns 83 may overlap the respective lower impurity diffusion region 87. The first diffusion regions 39 and the lower impurity diffusion region 87 may be formed to contact the first node plugs 78 in the respective active regions 15 and the lower body growth layer 56. The lower impurity diffusion region 87 may have the same conductivity as the first diffusion regions 39.

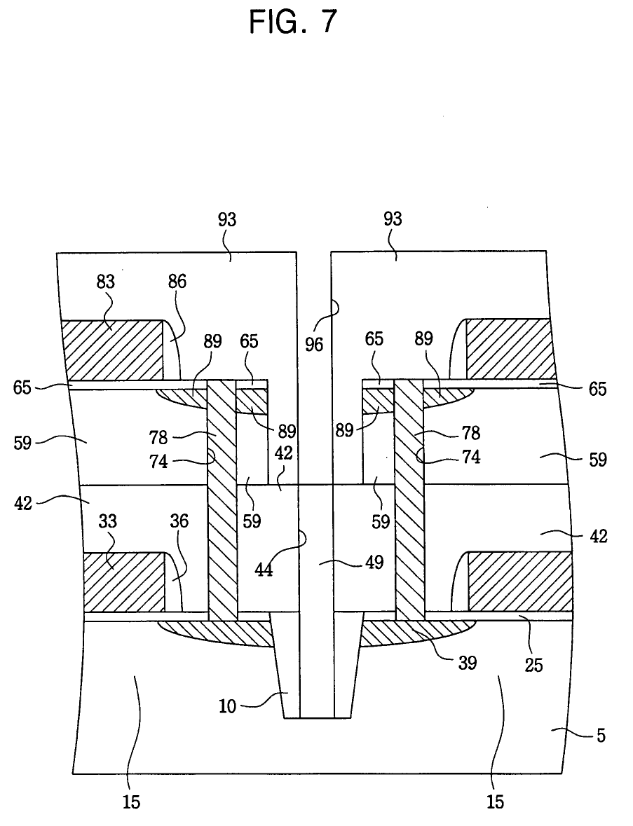

A photoresist pattern (not shown) may be formed on the second gate insulating layer 65 and may to cover the first node plugs 78 and the second gate patterns 83. The photoresist pattern may expose a portion of the lower body growth layer 56 that is directly above the device isolation layer 10. The photoresist pattern may be formed using a general semiconductor photolithography process. The lower body growth layer 56 may be etched using the photoresist patterns as an etching mask and the buried insulating layer 42 as an etch buffer layer. The etching may yield a structure having second diffusion regions 89, lower body regions 59 and a lower substrate plug 49, as shown in FIG. 7.

The lower body regions 59 on the buried insulating layer 42 may expose a portion of the buried insulating layer 42. The lower body regions 59 may be spaced apart form each other and may overlap the respective active regions 15. The lower substrate plug 49 may be formed in the buried insulating layer 42 and the device isolation layer 10. The lower substrate plug 49 may be disposed between the lower body regions 59 and may contact the substrate 5.

The second diffusion regions 89 may surround the first node plugs 78 in the lower body regions 59. After the formation of the second diffusion regions 89, the lower body regions 59 and the lower substrate plug 49, the photoresist pattern may be removed from the substrate 5.

A protective insulating layer 93 may be formed to cover the lower body regions 59 and the buried insulating layer 42. The protective insulating layer 93 may be formed of a material having the same etching rate as the buried insulating layer 42. In another implementation, the protective insulating layer 93 may be formed of a material having a different etching rate from the buried insulating layer 42.

Subsequently, a photoresist layer (not shown) may be formed on the protective insulating layer 93. The photoresist layer may have an opening exposing a portion of the protective insulating layer 93. The photoresist layer may be formed using a general semiconductor photolithography process. The protective insulating layer 93 may be etched using the photoresist layer as an etching mask to form an upper contact hole 96, as shown in FIG. 7. The upper contact hole 96 may expose the lower substrate plug 49. After the formation of the upper contact hole 96, the photoresist layer may be removed from the substrate 5.

An upper body growth layer (not shown) may be formed on the protective insulating layer 93. The upper body growth layer may fill the upper contact hole 96. The upper body growth layer may be formed to have the same structure as the lower body growth layer 56, as described above. For example, the upper body growth layer may have an upper substrate plug layer and an upper body layer that respectively correspond to the lower substrate plug layer 48 and the lower body layer 53 described above. The upper substrate plug layer may be single-crystalline, e.g., single-crystalline silicon, and may be formed using the lower substrate plug 49 as a seed and performing the selective epitaxial process. Accordingly, the upper substrate plug layer may fill the upper contact hole 96.

The upper body layer may be formed on the protective insulating layer 93, and the top surface of the upper substrate plug layer may be formed at the substantially same level as the top of the protective insulating layer 93. The upper body layer may be formed using, e.g., amorphous silicon. In another implementation, the upper body growth layer may be formed using only the upper body layer directly contacting the substrate 5. Subsequently, a general semiconductor annealing process may be performed on the upper body growth layer. During the performance of the annealing process, heat may be applied to the substrate 5 having the upper body growth layer in nitrogen ambient for a predetermined time.

Where the upper substrate plug layer is formed under the upper body layer, the annealing process may change the upper body layer from amorphous to single-crystalline using the upper substrate plug layer as a seed. Where the upper body layer directly contacts the substrate 5, the annealing process may change the upper body layer from amorphous to single-crystalline using the substrate 5 as a seed.

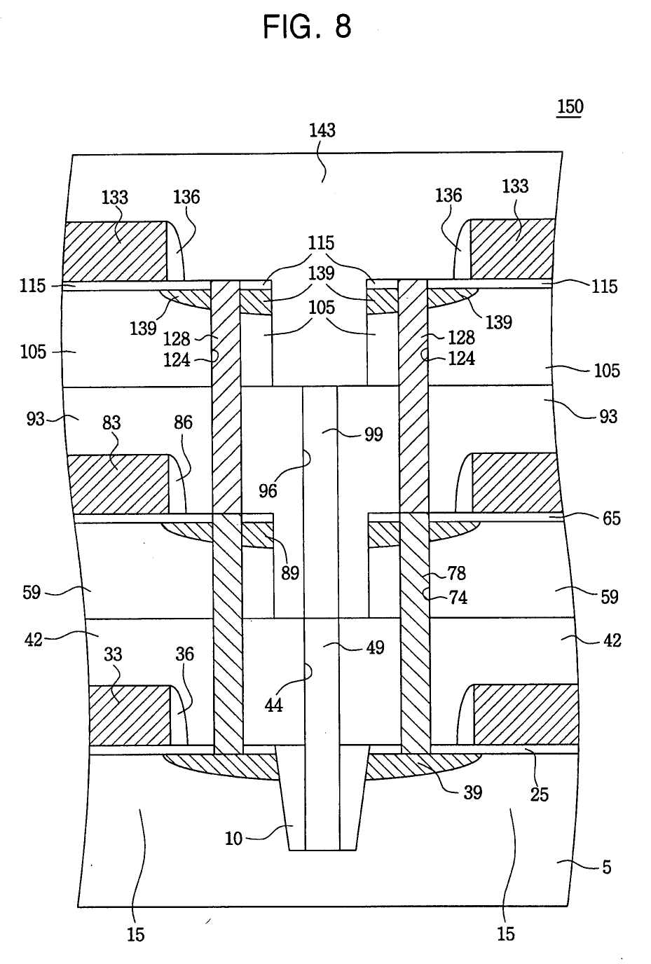

After the annealing process, a third gate insulating layer 115 may be formed on the upper body layer, as shown in FIG. 8. The third gate insulating layer 115 may be formed using the same material as the second gate insulating layer 65. A photoresist layer (not shown) may be formed on the third gate insulating layer 115. The photoresist layer may have openings exposing portions of the third gate insulating layer 115. The photoresist layer may be formed by performing a general semiconductor photolithography process. The third gate insulating layer 115, the upper body growth layer and the protective insulating layer 93 may be sequentially etched using the photoresist layer as an etching mask to form second contact holes 124. The second contact holes 124 may be formed to expose portions of the respective lower body regions 59, and may pass through the third gate insulating layer 115, upper body growth layer and protective insulating layer 93. After the formation of the second contact holes 124, the photoresist layer may be removed from the substrate 5.

Second node plugs 128 may fill the respective second contact holes 124. The second node plugs 128 may be formed to contact the respective lower body regions 59. The second node plugs 128 may be formed using, e.g., metal nitride and metal stacked thereon, doped polysilicon, etc. Subsequently, third gate patterns 133 may be formed on the third gate insulating layer 115. The third gate patterns 133 may be spaced apart from the second node plugs 128. The third gate patterns 133 may be have the same structure as the second gate patterns 83 in a volatile or nonvolatile device.

Third gate spacers 136 may respectively be formed on sidewalls of the third gate patterns 133. The third gate spacers 136 may be formed using the same material as the second gate spacers 86. An upper impurity diffusion region (not shown), which will form third diffusion regions 139 as described below, may be formed in the upper body growth layer using the third gate patterns 133 and the third gate spacers 136 as a mask. The upper impurity diffusion region may correspond to the lower impurity diffusion region 87 of FIG. 6. The third gate patterns 133 may overlap the upper impurity diffusion region. The second diffusion regions 89 and the upper impurity diffusion region may be formed to contact the second node plugs 128 in the lower body regions 59 and the upper body growth layer. The upper impurity diffusion region may be formed to have the same conductivity as the lower impurity diffusion regions 87.

A photoresist pattern (not shown) may be formed on the third gate insulating layer 115 and may cover the second node plugs 128 and the third gate patterns 133. The photoresist pattern may expose the upper body growth layer directly above the device isolation layer 10. The photoresist pattern may be formed using a general semiconductor photolithography process. The upper body growth layer may be etched using the photoresist pattern as a mask and using the protective insulating layer 93 as an etching buffer layer. This may yield a structure having the third diffusion regions 139, upper body regions 105 and an upper substrate plug 99, as shown in FIG. 8.

The upper body regions 105 may be on the protective insulating layer 93 and may expose a portion of the protective insulating layer 93. The upper body regions 105 may be spaced apart from each other and may overlap the respective lower body regions 59. The upper substrate plug 99 may be formed in the protective insulating layer 93 and may contact the lower substrate plug 49. The upper substrate plug 99 may be formed between the upper body regions 105.

The third diffusion regions 139 may surround the second node plugs 128 in the upper body regions 105. After the formation of the third diffusion regions 139, the upper body regions 105 and the lower substrate plug 99, the photoresist pattern may be removed form the substrate 5.

In an implementation (not shown), one or more additional active layers may be formed by repeating the processes described above, i.e., another protective insulating layer, contact hole and body growth layer may be formed and the body growth layer annealed to form a single-crystalline plug and body region structure. Another gate insulating layer having contact holes may be formed thereon, and node plugs may be formed therein. After the node plugs are formed, additional gate patterns, gate spacers, and an impurity diffusion region may be formed, and the resulting structure may be etched to form respective body regions, diffusion regions and a substrate plug.

Referring again to FIG. 8, a planarization insulating layer 143 may be formed. The planarization insulating layer 143 may cover the upper body regions 105 and the protective insulating layer 93. The planarization insulating layer 143 may be formed of a material having the same etching rate as the protective insulating layer 93, or may be formed of a material with a different etching rate from the protective insulating layer 93.

As described above, embodiments of the present invention provide a semiconductor device having a substrate plug and a method of forming the semiconductor device. One or more body regions of single-crystalline material may be formed on an active region, which may enhance the electrical characteristics of the semiconductor device. Such a structure may be advantageous for multilevel devices having sub-micron design rules.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device, comprising:
a device isolation layer disposed in a substrate and defining an active region;
a first gate pattern on the active region;
a first insulating layer on the substrate and the first gate pattern;
a first body region on the first insulating layer; and
a first substrate plug extending from the substrate into the first insulating layer, the first substrate plug penetrating the device isolation layer and contacting the substrate under the device isolation layer.

2. The device as claimed in claim 1, further comprising:
a second insulating layer on the first body region and the first insulating layer;
a second body region on the second insulating layer; and
a second substrate plug extending from the first substrate plug into the second insulating layer.

3. The device as claimed in claim 2, wherein the active region, the first and second body regions, and the first and second substrate plugs include a single-crystalline material.

4. The device as claimed in claim 3, wherein the single-crystalline material is single-crystalline silicon.

5. The device as claimed in claim 1, wherein the first body region is disposed on a first side of the first substrate plug, the device further comprising another body region on the first insulating layer, wherein:
the other body region is on a same plane as the first body region, and
the other body region is disposed on a second side of the first substrate plug opposite the first side.

6. The device as claimed in claim 1, further comprising:
a first diffusion region in the active region between the first gate pattern and the first substrate plug;
a second gate pattern on the first body region;
a second diffusion region in the first body region, the second diffusion region being between the second gate pattern and the first substrate plug; and
a first node plug extending through the first insulating layer and electrically connecting the first diffusion region to the second diffusion region.

7. The device as claimed in claim 6, wherein:
the first node plug and the first substrate plug extend in parallel from the substrate, and
the first node plug extends beyond the first substrate plug.

8. The device as claimed in claim 6, further comprising a second insulating layer on the second gate pattern and the first body region, wherein:
the second insulating layer includes a lower portion that extends toward the substrate beyond the second diffusion region, and
a second substrate plug is disposed in the lower portion, the second substrate plug contacting the first substrate plug.

9. The device as claimed in claim 6, further comprising a spacer on a sidewall of the first gate pattern, wherein:
the spacer is between the first gate pattern and the first node plug, and
the first node plug is between the spacer and the first substrate plug.

10. The device as claimed in claim 1, wherein the device is a volatile memory device.

11. The device as claimed in claim 1, wherein the device is a nonvolatile memory device.

12. A method of forming a semiconductor device, comprising:
forming a device isolation layer in a substrate, the device isolation layer defining an active region;
forming a first gate pattern on the active region;
forming a first insulating layer on the substrate and the first gate pattern;
forming a first body region on the first insulating layer; and
forming a first substrate plug that extends from the substrate into the first insulating layer, the first substrate plug penetrating the device isolation layer and contacting the substrate under the device isolation layer.

13. The method as claimed in claim 12, wherein forming the first body region and the first substrate plug includes:
forming a first body growth layer that extends from the substrate through the device isolation layer to at least partially cover the first insulating layer, and
removing a portion of the first body growth layer that directly overlies the device isolation layer.

14. The method as claimed in claim 13, wherein forming the first body region and the first substrate plug further includes:
forming a photoresist pattern on the first body growth layer, the photoresist pattern exposing the portion of the first body growth layer, and
etching the first body growth layer to expose a portion of the first insulating layer, wherein the photoresist pattern serves as an etching mask and the first insulating layer serves as an etching buffer layer.

15. The method as claimed in claim 13, wherein the first body growth layer includes a single-crystalline material.

16. The method as claimed in claim 13, further comprising:
forming a second insulating layer on the first body region and the first insulating layer, wherein the second insulating layer is disposed in an opening formed by the removal of the portion of the first body growth layer; and
forming a second substrate plug in the second insulating layer, the second substrate plug contacting the first substrate plug.

17. The method as claimed in claim 13, wherein forming the first body growth layer includes:
forming a photoresist layer on the first insulating layer, the photoresist layer exposing a portion of the first insulating layer that directly overlies the device isolation layer;
forming a contact hole by etching the exposed portion of the first insulating layer and the device isolation layer using the photoresist layer as an etching mask, the contact hole exposing a portion of the substrate under the device isolation layer;
removing the photoresist layer;
forming a single-crystalline first substrate plug layer in the contact hole using the exposed portion of the substrate as a seed; and
forming a single-crystalline first body layer on the first insulating layer and the first substrate plug layer using the first substrate plug layer as a seed.

18. The method as claimed in claim 17, wherein:
forming the single-crystalline first substrate plug layer includes an epitaxial process, and
forming the single-crystalline first body layer includes annealing the first body layer to convert it from an amorphous material to a single-crystalline material.

19. The method as claimed in claim 12, further comprising:
forming a second insulating layer on the first body region and on the first substrate plug;
forming a second body region on the second insulating layer; and
forming a second substrate plug that extends from the first substrate plug into the second insulating layer.

20. The method as claimed in claim 12, further comprising:
forming a first diffusion region in the active region between the first gate pattern and the first substrate plug;
forming a second gate pattern on the first body region;
forming a second diffusion region in the first body region, the second diffusion region being between the second gate pattern and the first substrate plug; and
forming a first node plug that extends through the first insulating layer and electrically connects the first diffusion region to the second diffusion region.
